(19) United States
(12) Patent Application Publication
(10) Pub. No.: US 2013/0015878 A1
(43) Pub. Date: Jan. 17, 2013

(54) POWER SYSTEM FAULT ZONE DETECTION

(71) Applicants: Nuwan Dileepa Perera, Winnipeg (CA); Krishnaswamy Gururaj Narendra, Winnipeg (CA); David James Fedirchuk, Ile Des Chenes (CA)

(72) Inventors: Nuwan Dileepa Perera, Winnipeg (CA); Krishnaswamy Gururaj Narendra, Winnipeg (CA); David James Fedirchuk, Ile Des Chenes (CA)

(73) Assignee: ERLPhase Power Technologies Limited, Winnipeg (CA)

(21) Appl. No.: 13/527,012

(22) Filed: Jun. 19, 2012

Related U.S. Application Data
(60) Provisional application No. 61/498,817, filed on Jun. 20, 2011.

(51) Int. Cl. G01R 31/40

(52) U.S. Cl. 324/764.01

(57) ABSTRACT

A system, method, and apparatus for power transmission fault zone detection. Each phase of a three-phase current in the power system is monitored, a modal component is determined from the three-phase current, high frequency transients in the modal component are extracted using wavelet packet transformation, and a travelling wave front is detected in the modal component indicating the fault. A wave sign is determined and the signs of two travelling waves are logically combined to determine whether or not the fault is within a protected zone.

### CROSS REFERENCE TO RELATED APPLICATIONS

This application claims the benefit of priority of U.S. Provisional Patent Application No. 61/498,817 filed Jun. 20, 2011, which is incorporated herein by reference in its entirety.

### FIELD

The present disclosure relates generally to fault detection. More particularly, the present disclosure relates to fault zone detection for power systems.

### BACKGROUND

Transmission lines, busbars and transformers are considered as main elements in electrical power system. Any faults happen associated with these elements need to be detected and isolated as soon as they occur. Therefore high speed and secured protection is essential to maintain a reliable power system to satisfy day today customer needs. Conventionally, the transmission systems are protected using impedance relays whereas; the elements such as busbars and transformers are protected using differential relays. Although these methods are being used for almost all protection schemes, their performance is not satisfactory under some practical scenarios.

The series compensated transmission lines is one of such examples. The voltage reversal, current reversal or both voltage and current reversals occur during faults can be considered as main challenges in protecting compensated transmission lines using distance relays. Furthermore, unpredictable behavior of the capacitors and other associated components (such as MOV, air-gap, etc.) during faults, may also lead to under-reach or over-reach problems. On the other hand, the conventional differential relays used to protect busbars and transformers may also mal-operate in some situations. The current transformer saturation during close-in external faults and the subsidence currents present after clearing external faults are the common failures reported with respect to the conventional differential relays.

It is, therefore, desirable to provide a method, apparatus, and system for identifying faults and determining whether the fault is inside or outside of a protected zone.

### SUMMARY

It is an object of the present disclosure to obviate or mitigate at least one disadvantage of previous methods, systems, and apparatus for fault detection.

The motivation for this innovation is to develop fast, reliable and secured protection concept that can be used identify faults in transmission lines, busbars, transformers, etc. irrespective of any series or shunt elements present inside the protected zone, current transformer saturation, dc offset, etc.

The use of high frequency transients have several benefits over the conventional protection such as high speed, independent of current transformer saturation, dc offset, power swing, etc. This innovation involves the use of high frequency transients (extracted using wavelet packet transform) originating from the faults to identify the faulted zones. The results obtained using detailed simulation study showed the capability of implementing a reliable protection scheme using the proposed concept. Furthermore, this method uses a minimal sampling rate (96-samples/cycle) in contrast to the similar (transient based) methods reported previously.

This disclosure relates to a high speed fault zone detection used for power system elements (such as transmission lines, cables, transformers, busbars, generators etc.) using wavelet packet transform. This protection method and system provides reliable and secure protection against faults, irrespective of the effects of any series or shunt elements present inside the protected zone.

In one embodiment, the method, system, and apparatus of the present disclosure may be applied to series compensated transmission lines that are difficult to protect using conventional impedance relays. The subject of this disclosure may also be adopted to enhance the security of conventional differential relays used to protect power system elements such as transformers and busbars.

In a first aspect, the present disclosure provides a method of detecting a fault in a power system, including monitoring each phase of a three-phase current in the power system, determining a modal component from the three-phase current, extracting high frequency transients in the modal component using wavelet packet transformation, and detecting a travelling wave front in the modal component indicating the fault.

In an embodiment, the modal component includes an aerial modal component or a ground modal component or both.

In an embodiment, the wavelet packet decomposition comprises decomposing the modal component into at least two scales.

In an embodiment, the wavelet packet decomposition comprises decomposing the modal component into at least four frequencies.

In an embodiment, a scale-2, frequency-3 component of the wavelet packet transform (DD2) provides a wave sign.

In an embodiment, the wave sign is positive, indicating the travelling wave front is a positive wave front.

In an embodiment, the wave sign is negative, indicating the travelling wave front is a negative wave front.

In an embodiment, the monitoring of each phase of the three-phase current is at substantially 96 samples/cycle.

In an embodiment, the travelling wave front is detected less than 3 ms after the fault.

In an embodiment, the monitoring of each phase of the three-phase current are not time synchronized.

In an embodiment, the power system includes a direct current (DC) transmission system.

In a further aspect, the present disclosure provides a method of detecting a fault in a power system, including at a first location, monitoring each phase of a first three-phase current in the power system, determining a first modal component from the first three-phase current, extracting first high frequency transients in the first modal component using wavelet packet transformation, and detecting a first travelling wave front in the first modal component indicating the fault, at a second location, monitoring each phase of a second three-phase current in the power system, determining a second modal component from the second three-phase current, extracting second high frequency transients in the second modal component using wavelet packet transformation, and detecting a second travelling wave front in the second modal component indicating the fault, the first location and the second location defining a protected zone there-between.

In an embodiment, each modal component includes an aerial modal component or a ground modal component or both.

In an embodiment, the wavelet packet decomposition comprises decomposing each modal component into at least two scales.

In an embodiment, the wavelet packet decomposition comprises decomposing each modal component into at least four frequencies.

In an embodiment, a scale-2, frequency-3 component of the wavelet packet transform (DD2) provides a wave sign for each travelling wave.

In an embodiment, the wave sign for the first travelling wave and the second travelling wave are logically combined to determine whether or not the fault is within the protected zone.

In a further aspect, the present disclosure provides a fault detection device for a power system including a first current monitor for monitoring each phase of a three-phase current in the power system, a processor for determining a modal component from the three-phase current and extracting high frequency transients in the modal component using wavelet packet transformation, detecting a travelling wave front in the modal component, and a wave sign of the travelling wave front, and a fault indicator.

In an embodiment, the fault detection further includes a communications port for exchanging modal component information with a second fault detection device, the fault detection device and the second fault detection device defining a protected zone there-between.

In an embodiment, the fault detection device comprises a relay and a circuit breaker.

In an embodiment, the technique is independent of system frequency or any harmonics or sub-harmonics present in the system and applicable in dc transmission systems as well.

In an embodiment, the technique is easily adoptable with conventional protection schemes with conventional current transformers.

In an embodiment, if end to end relays are used, only a logical information exchange is required.

In an embodiment, communication is not required for unit protection such as transformers, busbars, etc.

Other aspects and features of the present disclosure will become apparent to those ordinarily skilled in the art upon review of the following description of specific embodiments in conjunction with the accompanying figures.

### BRIEF DESCRIPTION OF THE DRAWINGS

Embodiments of the present disclosure will now be described, by way of example only, with reference to the attached Figures.

FIG. 1 is an arrangement of the present disclosure for detection of a fault and identification of whether the fault is inside or outside of a protected zone;

FIG. 2 is a schematic of the steps in travelling wave front identification;

FIG. 3 is a schematic of wavelet packet transform;

FIG. 4 depicts a mother wavelet;

FIG. 5 is a graph of three-phase current signals, aerial modal component, and wavelet packet coefficient observed during a fault;

FIG. 6 is a graph of observed phase current measurements and wavelet packet coefficient at R1 and R2, for an internal fault, F1;

FIG. 7 is a graph of observed phase current measurements and wavelet packet coefficient at R1 and R2, for an external fault, F2;

FIG. 8 depicts an embodiment of the present disclosure, including information exchanged between R1 and R2 during a fault;

FIG. 9 is a logic diagram for internal fault identification;

FIG. 10 is an embodiment of the present disclosure, applied to a relay arrangement for transmission line protection; and

FIG. 11 is an embodiment of the present disclosure, applied to a relay arrangement for transformer protection.

### DETAILED DESCRIPTION

Generally, the present disclosure provides methods, systems, and apparatus for power system protection.

In one embodiment, disclosed is a sub-cycle fault zone detection technique using a minimal sample based wavelet packet transform.

### Basic Embodiment

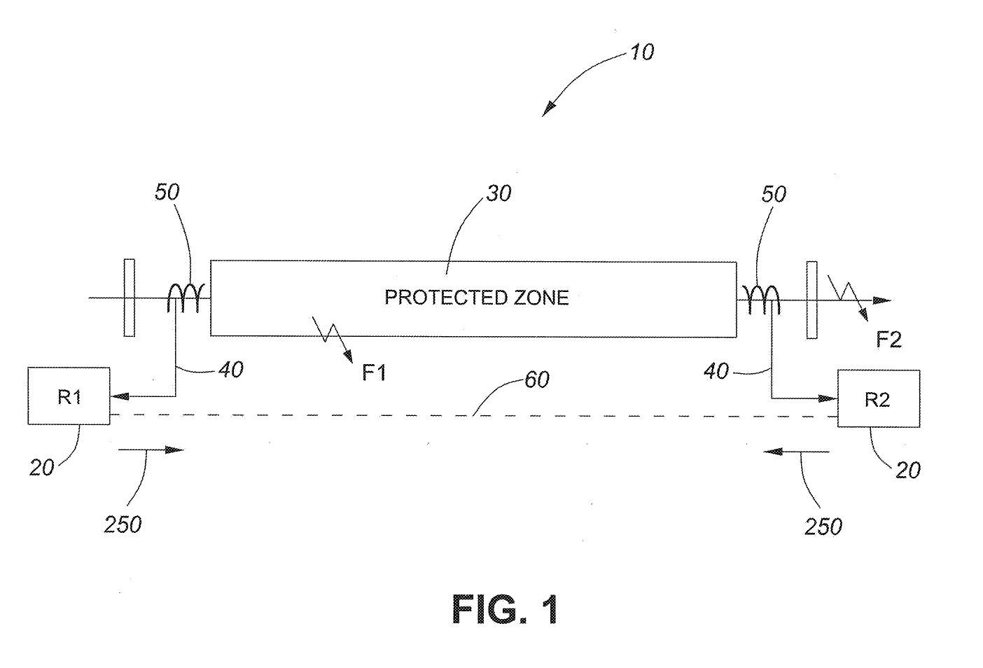

FIG. 1 is an arrangement for current measurement protection scheme in a power system.

In a power system 10 relays 20 (R1 and R2) are located at the boundaries of a protected zone 30. Current signals representing currents 40 (I1 and I2) are used as the inputs for the relays 20 (R1 and R2).

In this embodiment, current transformers 50 are arranged in a way that they measure the currents 40 entering (or leaving) the protected zone 30. A fault inside the region of the current transformers 50 (inside the protected zone 30) such as F1 is referred to as an internal fault whereas any fault outside the region of the current transformers 50 (outside the protection zone 30) such as F2 is referred to as an external fault.

Each relay 20 is capable of identifying ‘travelling wave fronts’ originating from a fault using high frequency current transients extracted from wavelet packet transform. These travelling wave fronts are determined by the relays on boundaries and are combined to categorize a fault as an internal fault such as F1 or an external fault such as F2. A communication medium 60 is used to exchange the fault direction information in a logical form between the relays 20 (R1 and R2). The communication medium 60 may include, for example, a telecommunications network, copper or other conductor, fiber optics, Ethernet over copper, Ethernet over fiber optics, power line carrier, microwave other media known to one skilled in the art suitable for conveying a signal, for example a binary signal between R1 and R2. In embodiments of the disclosed power system fault zone detection disclosed, the signal may be encoded or encrypted or both.

The details about wave front identification, internal/external fault identification and operation of the protection scheme under different fault scenarios are described below.

### Travelling Wave Front Identification Using Wavelets

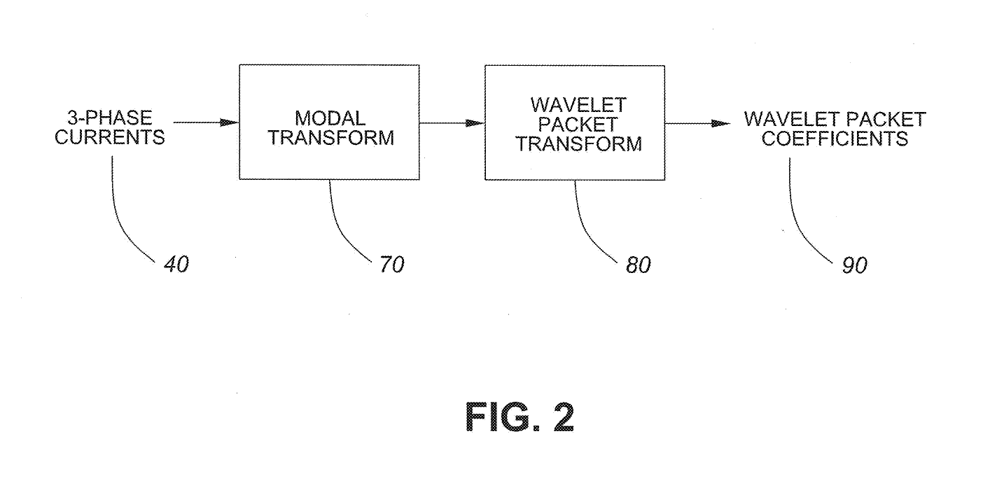

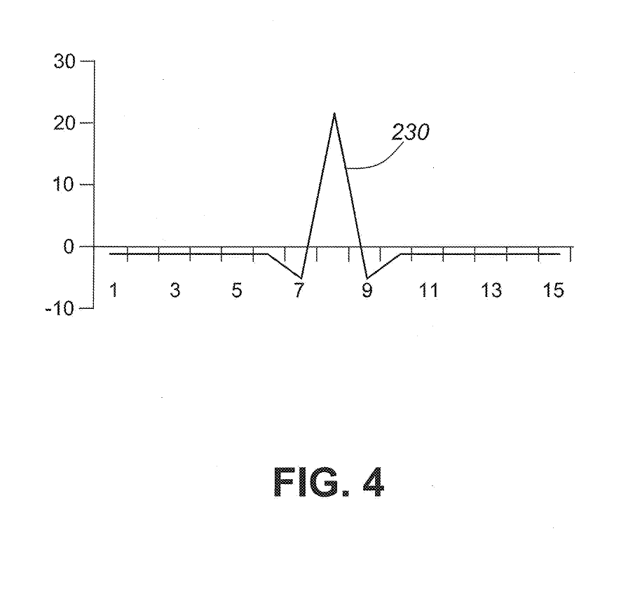

FIG. 2 depicts the main steps involved in the method of detecting a travelling wave front 240 (see FIG. 4) from a fault F1 or F2 in a power system 10.

First, the three-phase currents 40 are measured or monitored from the power system 10 (FIG. 1). Then modal transform 70 is used to transform the three-phase currents 40 into two modal quantities using (1) and (2).

I_{M1}=Iₐ−2I_{b}+2I_{c} (1)

I_{M2}=Iₐ+I_{b}+I_{c} (2)

Here, I_{M1} and I_{M2} are referred to as aerial modal component 72 and ground modal component 74 respectively. The aerial modal component is significant during all types of faults whereas the ground modal component is significant during ground faults only.

Next, ‘wavelet packet transform’ 80 is used to extract the high frequency transients embedded in the modal quantities during a fault. The wavelet packet transform 80 is a technique that is used to decompose a given signal into different frequency components to provide wavelet packet coefficients 90.

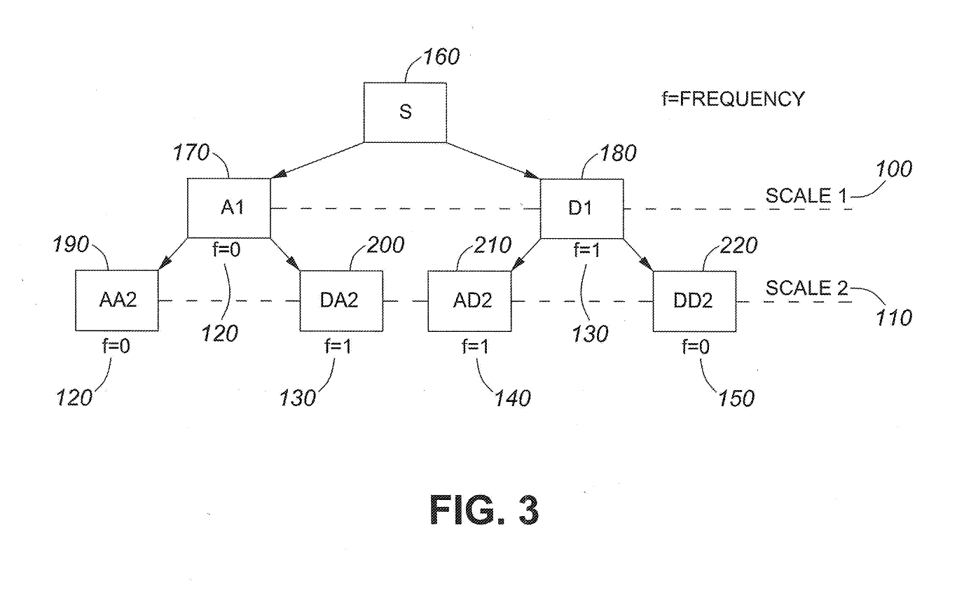

FIG. 3 shows wavelet packet decomposition of a signal s, labeled 160, for example a current 40, into two scales (also known as levels or depths), specifically scale 1 labeled 100 and scale 2 labeled 110. The parameter f is used to label different frequency bands at each level, specifically f=0, f=1, f=2, f=3, labeled 120, 130, 140, 150 respectively. This provides several components (in the example, six components) A1, D1, AA2, DA2, AD2, DD2 labeled 170, 180, 190, 200, 210, 220 respectively.

The scale-2, frequency-3 component of the wavelet packet transform (DD2) 220 of the modal component is used to determine the sign of a travelling wave front. If the highest amplitude of the wavelet packet coefficient is positive, the ‘travelling wave front’ is considered as a ‘positive wave’ with reference to the shape of the mother wavelet, see 230 FIG. 4, and vice versa.

FIG. 4 depicts the shape of the mother wavelet 230 used herein, as an example for a travelling wave front 240. This is a positive wave.

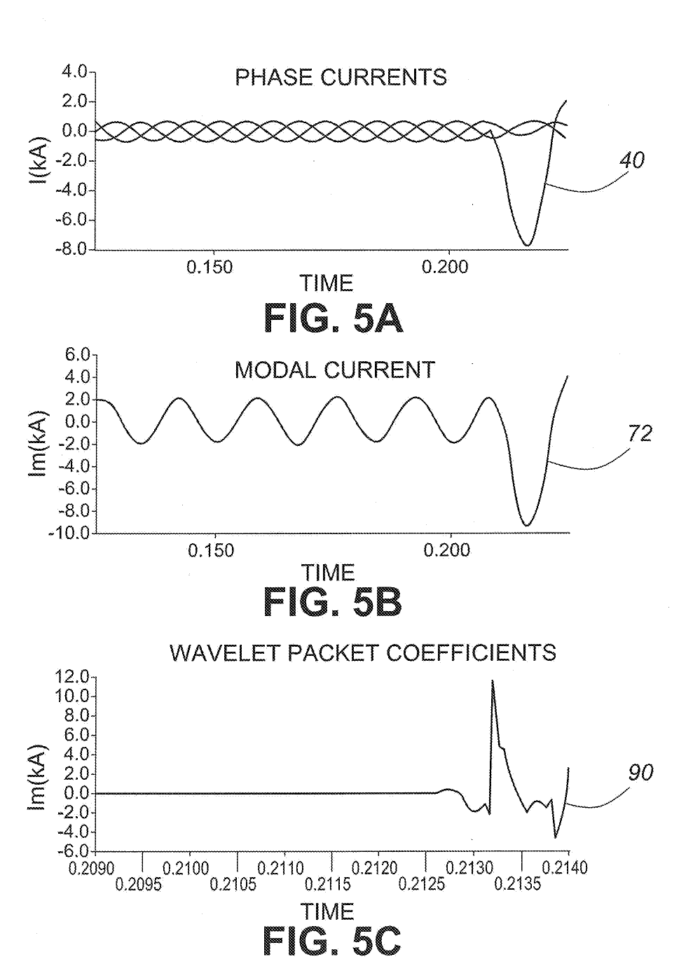

FIG. 5 depicts the variations of the measured three-phase current 40, the aerial modal component 72, and the wavelet packet coefficient 90 during an example fault, over time. In this example case, the sign of the highest wavelet packet coefficient 90 is positive and therefore it is considered as a positive wave front.

Note: Although the modal transform given in (1) and (2) is used here, this method is applicable for other types of standard modal transforms such as a Clarke Transform.

### Fault Characterization

The signs of the travelling wave fronts (corresponding to each of the modal components) determined at the boundaries are combined to categorize a fault or faults as internal or external as described below.

In a power system 10 relays 20 (R1 and R2) are located at the boundaries of a protected zone 30 (see FIG. 1). Current signals representing currents 40 (I1 and I2) are used as the inputs for the relays 20 (R1 and R2) (see FIG. 1).

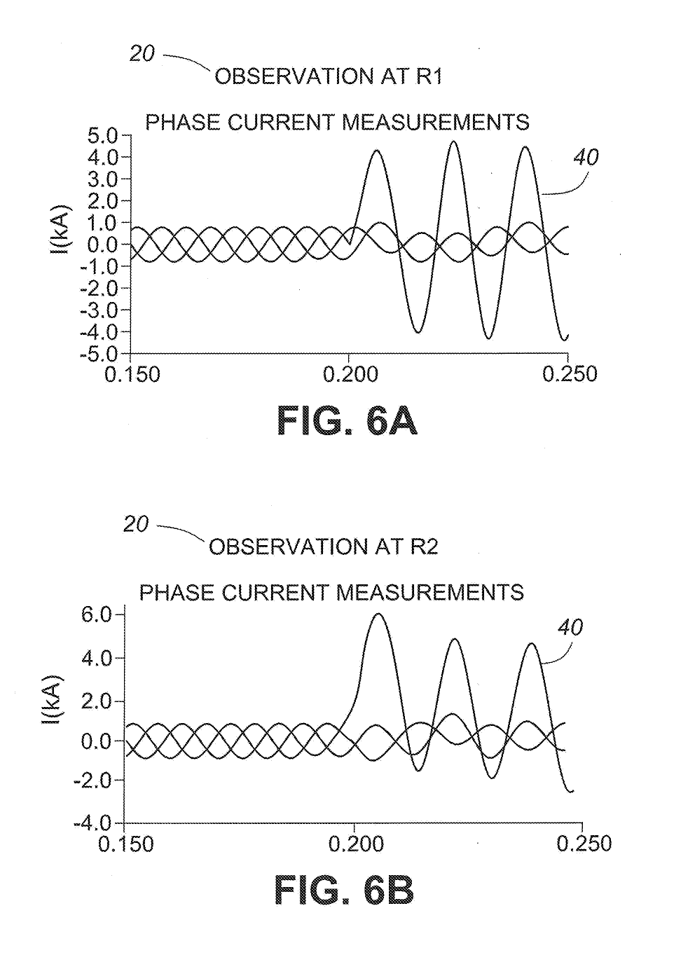

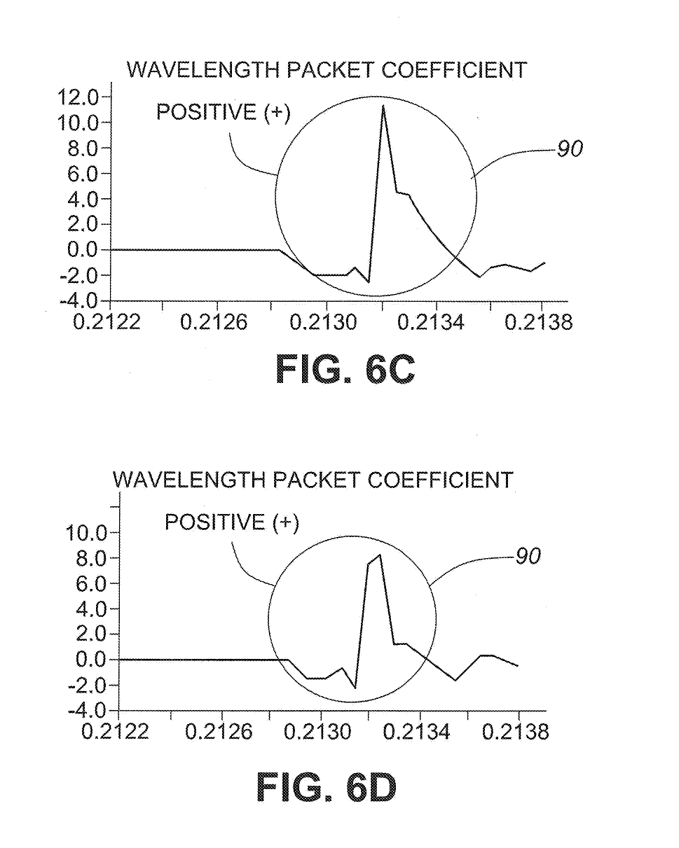

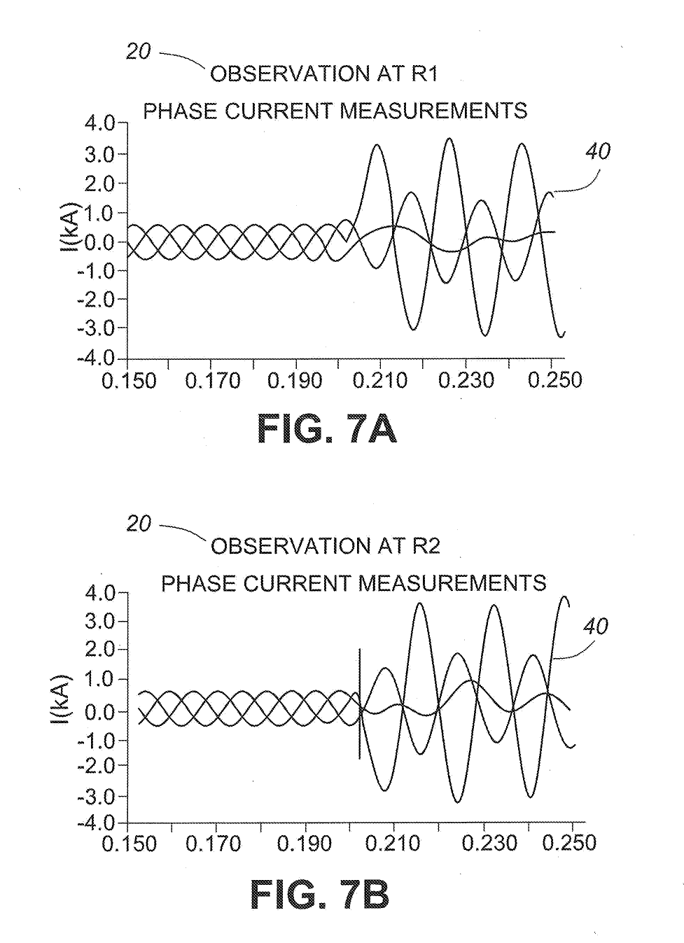

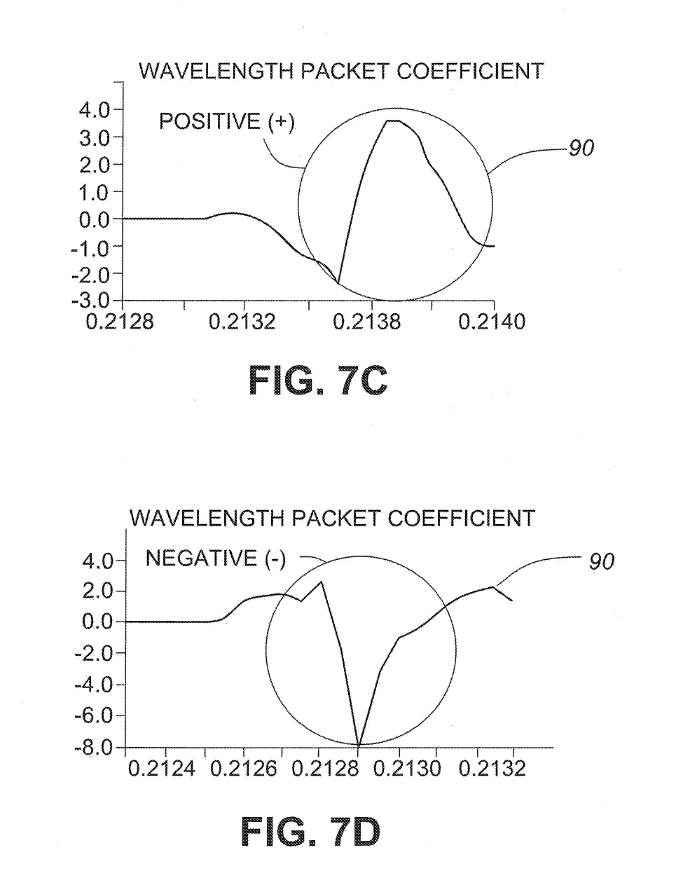

FIGS. 6 and 7 show the variation of three-phase current signals representing currents 40 and wavelet packet coefficients 90 observed by relays 20 (R1 and R2) during an internal fault (F1) and an external fault (F2) respectively.

As it can be seen from FIG. 6, the highest amplitude of the wavelet packet coefficients observed at relays 20 (R1 and R2) are equal in sign for the internal fault (F1), specifically positive at both relays 20 (R1 and R2).

However, as it can be seen from FIG. 7, the signs are opposite for the external fault (F2), specifically positive at relay 20 (R1) and negative at relay 20 (R2).

The comparison of the sign information obtained at both ends, of the protection zone 30 (see FIG. 1) can be used to identify the internal faults.

### Information Exchange Process During Faults

The sign information corresponding to each modal component (aerial modal component 72 and ground modal component 74) is compared separately. The process of information exchange or communication during internal faults (F1) and external faults (F2) is explained below.

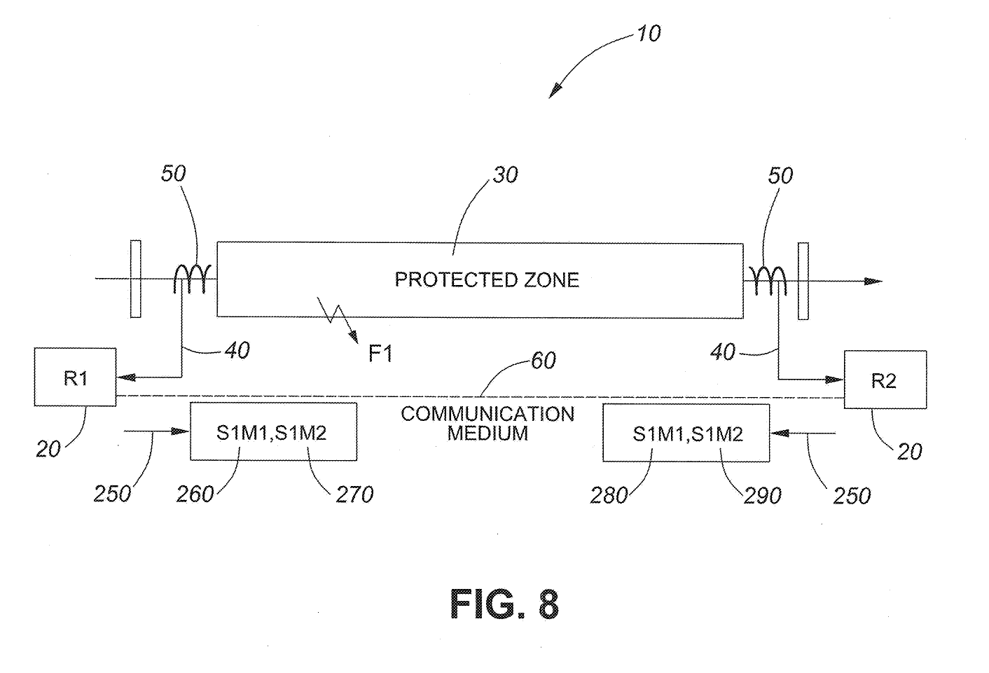

FIG. 8 shows the process of information exchange or communication during faults to identify internal faults (F1). As in FIG. 1, in the power system 10 relays 20 (R1 and R2) are located at the boundaries of the protected zone 30. Current signals representing currents 40 (I1 and I2) are used as the inputs for the relays 20. The current transformers 50 are arranged in a way that they measure the current 40 entering (or leaving) the protected zone 30.

Logical information 250 corresponding to the signs of the highest packet outputs are exchanged or communicated between the relays 20 (R1 and R2). Here, S1M1 labeled 260 and S1M2 labeled 270 denote the sign information determined by relay 20 (R1) and S2M1 labeled 280 and S2M2 labeled 290 denote the sign information determined by relay 20 (R2). The logical information 250 ‘1’ and ‘0’ is used to represent positive and negative correlations respectively. Sign information corresponding to each of the modal components is compared to identify internal faults (F1). In the event of an internal fault (F1), a protective action may be taken, for example activating a protective relay, circuit breaker or other protective device known to one skilled in the art (not shown).

### Logic for Internal Fault Detection

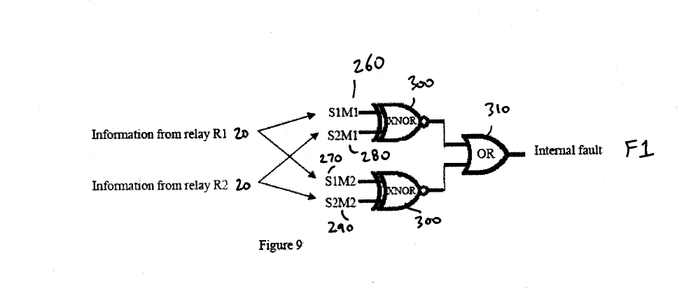

The basic logic for identification of a fault as an internal fault (F1) is shown in FIG. 9. Logical information 250 from relay 20 (R1) is shown as S1M1, S1M2 labeled 260, 270, and logical information 250 from relay 20 (R2) is shown as S2M1, S2M2 labeled 280, 290.

“XNOR” logic gates 300 are used to compare sign information. Then, a further logic gate, an “OR” logic gate 310, is used to combine sign information corresponding to both the aerial modal component 72 and the ground modal component 74.

In an embodiment disclosed, output of the ground modal component 74 is enabled during faults involved with ground only (e.g. ground faults).

### Application Example—Transmission Line

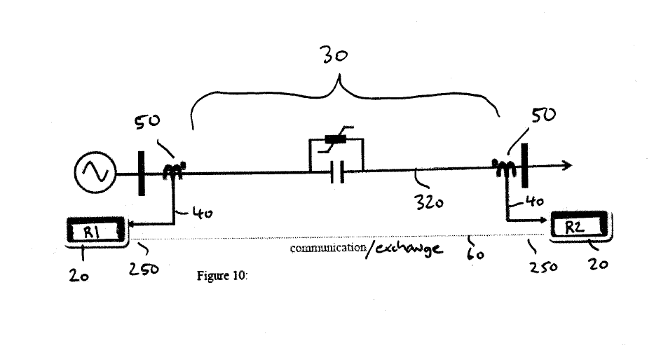

FIG. 10 depicts an embodiment of the present disclosure, applied to a transmission line 320 in the power system 10. In an embodiment, the transmission line 320 is a series compensated power transmission line.

The relays 20 (R1 and R2) are located at the boundaries of a protected zone 30. Current signals representing currents 40 (I1 and I2) are used as the inputs for the relays 20 (R1 and R2).

Logical information 250 is exchanged or communicated between the relays 20 (R1 and R2), for example via communication medium 60.

The configuration shown could be provided in a repeating pattern along the transmission line 320 to provide several protected zones 30 along the transmission line to provide segmented fault detection.

### Application Example—Transformer

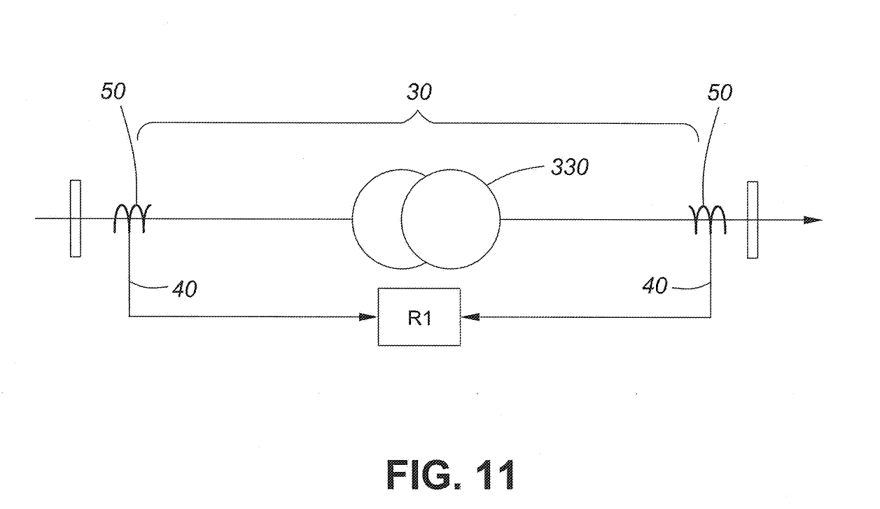

FIG. 11 depicts an embodiment of the present disclosure, applied to a transformer 330.

In this configuration, a relays 20 (R1) receives current signals representing current 40 from current transformers 50 at the boundaries of a protected zone 30.

There is no requirement of communication for transformer or busbar protection. In such cases, a single relay 20 can be used to implement the complete scheme as shown in FIG. 11.

In the preceding description, for purposes of explanation, numerous details are set forth in order to provide a thorough understanding of the embodiments. However, it will be apparent to one skilled in the art that these specific details are not required. In other instances, well-known electrical structures and circuits are shown in block diagram form in order not to obscure the understanding. For example, specific details are not provided as to whether the embodiments described herein are implemented as a software routine, hardware circuit, firmware, or a combination thereof.

Frequencies used herein, for example 60 Hz can be modified to other frequency power systems, such as 50 Hz. As an example, a sampling rate of 5760 Hz (96 samples/cycle) for 60 Hz would be 4800 Hz for a 50 Hz power system.

While not expressly shown, in the event of an internal fault F1 or external fault F2, or both, certain known actions may be undertaken, for example opening a circuit breaker or other protective action.

Embodiments of the disclosure can be represented as a computer program product stored in a machine-readable medium (also referred to as a computer-readable medium, a processor-readable medium, or a computer usable medium having a computer-readable program code embodied therein). The machine-readable medium can be any suitable tangible, non-transitory medium, including magnetic, optical, or electrical storage medium including a diskette, compact disk read only memory (CD-ROM), memory device (volatile or non-volatile), or similar storage mechanism. The machine-readable medium can contain various sets of instructions, code sequences, configuration information, or other data, which, when executed, cause a processor to perform steps in a method according to an embodiment of the disclosure. Those of ordinary skill in the art will appreciate that other instructions and operations necessary to implement the described implementations can also be stored on the machine-readable medium. The instructions stored on the machine-readable medium can be executed by a processor or other suitable processing device, and can interface with circuitry to perform the described tasks.

The above-described embodiments are intended to be examples only. Alterations, modifications and variations can be effected to the particular embodiments by those of skill in the art without departing from the scope, which is defined solely by the claims appended hereto.

What is claimed is:

1. A method of detecting a fault in a power system, comprising:
monitoring each phase of a three-phase current in the power system;
determining a modal component from the three-phase current;
extracting high frequency transients in the modal component using wavelet packet transformation; and
detecting a travelling wave front in the modal component indicating the fault.

2. The method of claim 1, wherein the modal component includes an aerial modal component or a ground modal component or both.

3. The method of claim 2, wherein the wavelet packet decomposition comprises decomposing the modal component into at least two scales.

4. The method of claim 3, wherein the wavelet packet decomposition comprises decomposing the modal component into at least four frequencies.

5. The method of claim 4, wherein a scale-2, frequency-3 component of the wavelet packet transform (DD2) provides a wave sign.

6. The method of claim 5, wherein the wave sign is positive, indicating the travelling wave front is a positive wave front.

7. The method of claim 5, wherein the wave sign is negative, indicating the travelling wave front is a negative wave front.

8. The method of claim 1, wherein the monitoring of each phase of the three-phase current is at substantially 96 samples/cycle.

9. The method of claim 1, wherein the travelling wave front is detected less than 3 ms from the fault.

10. The method of claim 1, wherein the monitoring of each phase of the three-phase current are not time synchronized.

11. The method of claim 1, wherein the power system includes a direct current (DC) transmission system.

12. A method of detecting a fault in a power system, comprising:
at a first location, monitoring each phase of a first three-phase current in the power system, determining a first modal component from the first three-phase current, extracting first high frequency transients in the first modal component using wavelet packet transformation, and detecting a first travelling wave front in the first modal component indicating the fault;
at a second location, monitoring each phase of a second three-phase current in the power system, determining a second modal component from the second three-phase current, extracting second high frequency transients in the second modal component using wavelet packet transformation, and detecting a second travelling wave front in the second modal component indicating the fault; and
the first location and the second location defining a protected zone there-between.

13. The method of claim 12, wherein each modal component includes an aerial modal component or a ground modal component or both.

14. The method of claim 13, wherein the wavelet packet decomposition comprises decomposing each modal component into at least two scales.

15. The method of claim 14, wherein the wavelet packet decomposition comprises decomposing each modal component into at least four frequencies.

16. The method of claim 15, wherein a scale-2, frequency-3 component of the wavelet packet transform (DD2) provides a wave sign for each travelling wave.

17. The method of claim 16, further comprising logically combining the wave sign for the first travelling wave and the second travelling wave to determine whether or not the fault is within the protected zone.

18. A fault detection device for a power system comprising:
a first current monitor for monitoring each phase of a three-phase current in the power system;
a processor for determining a modal component from the three-phase current and extracting high frequency transients in the modal component using wavelet packet transformation, detecting a travelling wave front in the modal component, and a wave sign of the travelling wave front; and
a fault indicator.

19. The fault detection device of claim 18, further comprising a communications port for exchanging modal component information with a second fault detection device, the fault detection device and the second fault detection device defining a protected zone there-between.

20. The fault detection device of claim 18, wherein the fault detection device comprises a relay.
